(19) United States
(12) Patent Application Publication
(10) Pub. No.: US 2003/0085776 A1
(43) Pub. Date: May 8, 2003

(54) Array type noise reduction filter

(75) Inventors: Byung Taek Kim, Kyungki-do (KR); Jeong Ho Yoon, Seoul (KR); Sung Yeol Park, Kyungki-do (KR); Min Kyu Park, Taeku (KR); Min Cheol Park, Suwon (KR)

Correspondence Address: LOWE HAUPTMAN GOPSTEIN GILMAN & BERNER, LLP, Suite 310, 1700 Diagonal Road, Alexandria, VA, 22314, US

(73) Assignee: Samsung Electro-Mechanics Co., Ltd.

(21) Appl. No.: 10/054,963

(22) Filed: Jan. 25, 2002

(30) Foreign Application Priority Data
Nov. 5, 2001 (KR) 2001-68602

(51) Int. Cl. H03H 7/01

(52) U.S. Cl. 333/185

(57) ABSTRACT

Disclosed herein is an array type noise reduction filter. The array type noise reduction filter has a plurality of noise reduction filters horizontally arranged within a single chip. A plurality of noise reduction filters each have a conductor layer and an inductance portion. The conductor layer is comprised of a ground portion arranged at approximately the center portion within the chip, and at least one capacitance portion arranged at at least one position over or under the ground portion. The inductance portion is arranged over or under the conductor layer. An inductance portion of another noise reduction filter adjacent to a noise reduction filter having an inductance portion arranged over the conductor layer is arranged under the conductor layer.

### BACKGROUND OF THE INVENTION

1. Field of the Invention

The present invention relates generally to array type noise reduction filters, and more particularly to an array type noise reduction filter, in which inductance portions are alternately arranged at opposite sides on the basis of a ground portion such that the inductance portions are separated by the ground portion so as to minimize crosstalk which is an electromagnetic interference phenomenon.

2. Description of the Prior Art

Generally, when electronic devices are operated, electromagnetic wave noises such as various types of power noises or clock pulse source noises exist within the devices. Especially, in mobile communication terminals, as power frequency becomes higher, great electromagnetic wave noise is generated.

Such electromagnetic wave noises are mutually propagated between circuits along circuit power lines or signal lines within electronic devices, thus causing incorrect operation of each device. Further, power noise or clock pulse source noise generated within an electronic device set is propagated to another electronic device set along a power supply line of the device set, thus causing interference with a normal operation of another electronic device set. On the other hand, a corresponding electronic device set can interfere with its normal operation due to noise propagated from another device. The interference phenomenon due to such electromagnetic wave noises is so called Electro-Magnetic Interference (EMI).

Therefore, for the purpose of performing normal operation of electronic devices, methods for reducing the electromagnetic wave noises must be considered in order to prevent this EMI when the devices are designed. Generally, a method for inserting a noise reduction filter between each circuit and each circuit power source of the electronic devices, or between each circuit and each clock pulse source of the electronic devices is used as a method for reducing the electromagnetic wave noises.

Recently, an array type noise reduction filter has been popularized as a commonly used noise reduction filter. The array type noise reduction filter is constructed in an array type such that a single chip has a plurality of noise reduction filters within it.

FIG. 1a is a schematic sectional view showing a conventional array type noise reduction filter 10. Referring to FIG. 1a, the array type noise reduction filter 10 comprises two noise reduction filters 10a and 10b. The noise reduction filters 10a and 10b each have first and second ground electrode layers 12 and 13, capacitance portions 14a and 15a or 14b and 15b, and an inductance portion 17a or 17b. The first and second ground electrode layers 12 and 13 are respectively arranged at the upper and lower portions of a chip 11. The capacitance portions 14a and 15a or 14b and 15b are formed inside each of the first and second ground electrode layers 12 and 13. The inductance portion 17a or 17b is formed in a coil pattern. The first and second ground electrode layers 12 and 13 function as common electrodes shared between the noise reduction filters 10a and 10b. Further, input and output ports (not shown) of each noise reduction filter are formed on the front and back surfaces of the chip 11. The input ports formed on the front surface of the chip 11 are each connected to one end of each of the inductance portions 17a and 17b, and the capacitance portions 14a and 15a, while the output ports formed on the back surface of the chip 11 are each connected to the other end of each of the inductance portions 17a and 17b, and the capacitance portions 14b and 15b.

In the array structure of the array type noise reduction filter 10, the first and second inductance portions 17a and 17b are symmetrically arranged adjacently to each other at the center portion of the chip 11, thus causing inductance coupling due to mutual inductance. In other words, crosstalk which is mutual electromagnetic interference can occur between the noise reduction filters 10a and 10b. Consequently, the array type noise reduction filter is problematic in that undesirable influence is generated between the filters 10a and 10b due to the mutual interference, thus causing the incorrect operation of each noise reduction filter.

FIG. 1b is a graphic view showing the electromagnetic interference characteristics of a conventional array type noise reduction filter. Referring to FIG. 1b, a full line represents characteristics of each noise reduction filter in the array type noise reduction filter, and a dotted line represents the electromagnetic interference characteristics generated between the noise reduction filters. As shown with the dotted line, in the conventional array type noise reduction filter, crosstalk occurs largely between the noise reduction filters. This is due to the mutual inductance generated between the filters arranged within a single chip, as described above. Therefore, such mutual inductance causes electromagnetic interference between the filters, thus deteriorating the filter characteristics of the array type noise reduction filter.

As described above, in this noise reduction filter technical field, a new array type noise reduction filter has been required for effectively preventing crosstalk from occurring due to the mutual inductance between the inductance portions of respective noise reduction filters.

### SUMMARY OF THE INVENTION

Accordingly, the present invention has been made keeping in mind the above problems occurring in the prior art, and an object of the present invention is to provide an array type noise reduction filter, in which a ground electrode is arranged at approximately the center portion within a chip, and inductance portions are alternately arranged over and under the ground electrode, such that inductance portions of adjacent filters are arranged to be spaced apart from each other on the basis of the ground electrode, thus preventing crosstalk due to mutual inductance generation from occurring.

In accordance with one aspect of the present invention, the above and other objects can be accomplished by the provision of an array type noise reduction filter, comprising a plurality of noise reduction filters horizontally arranged within a single chip, each comprising a conductor layer comprised of a ground portion arranged at approximately the center portion within the chip, and at least one capacitance portion arranged at at least one position over or under the ground portion, and an inductance portion arranged over or under the conductor layer; wherein an inductance portion of another noise reduction filter adjacent to a noise reduction filter having an inductance portion arranged over the conductor layer is arranged under the conductor layer.

According to a preferred embodiment, the ground portion is formed as a common electrode for a plurality of noise reduction filters, and the inductance portion is formed of a coil-shaped conductor pattern, thus simplifying the manufacturing process of the array type noise reduction filter.

According to another preferred embodiment, the capacitance portion can be comprised of a first capacitance portion arranged over the ground portion, and a second capacitance portion arranged under the ground portion opposite the first capacitance portion. In this case, the noise reduction filters are each formed in the shape of a π. On the other hand, each noise reduction filter employs only one capacitance portion such that noise reduction filters can be realized to each comprise one inductance portion and one capacitance portion.

In accordance with another aspect of the present invention, there is provided an array type noise reduction filter having a single chip shape, comprising a conductor layer comprised of a ground electrode horizontally arranged at approximately the center portion within the chip, and a plurality of capacitance portions each arranged at least one position over and under the ground electrode; and a plurality of inductance portions each arranged over or under the conductor layer at which a plurality of capacitance portions are respectively arranged, wherein a plurality of inductance portions are alternately arranged over and under the conductor layer such that any one inductance portion and its most adjacent inductance portion are separated by the ground electrode.

### BRIEF DESCRIPTION OF THE DRAWINGS

The above and other objects, features and other advantages of the present invention will be more clearly understood from the following detailed description taken in conjunction with the accompanying drawings, in which:

FIG. 1a is a schematic sectional view showing a conventional array type noise reduction filter;

FIG. 1b is a graphic view showing the electromagnetic interference characteristics of the conventional array type noise reduction filter;

FIG. 2a is a schematic sectional view showing an array type noise reduction filter according to a preferred embodiment of this invention;

FIG. 2b is a graphic view showing the improved electromagnetic interference characteristics of the array type noise reduction filter of this invention; and

FIG. 3 is a schematic perspective view showing another array type noise reduction filter having four noise reduction filters according to another preferred embodiment of this invention.

### DESCRIPTION OF THE PREFERRED EMBODIMENTS

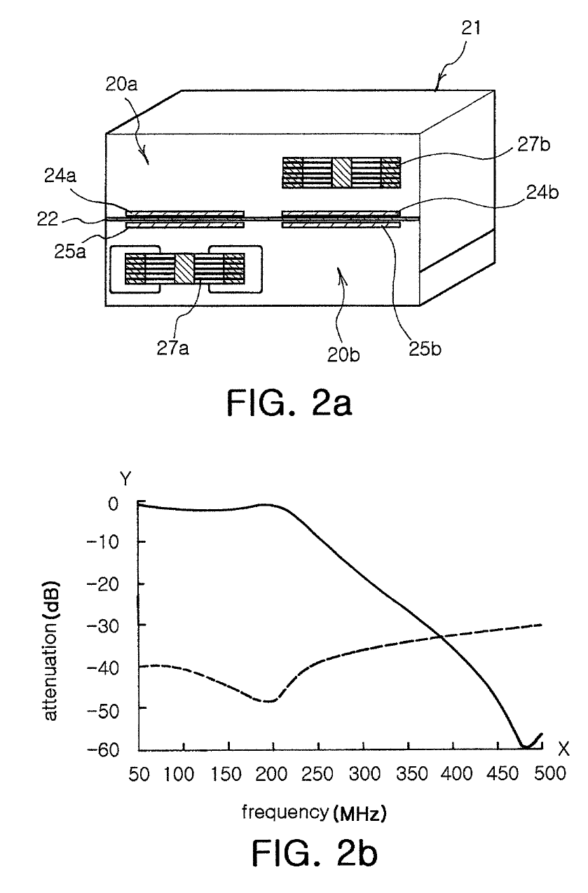

FIG. 2a is a schematic sectional view showing an array type noise reduction filter according to a preferred embodiment of this invention. Referring to FIG. 2a, the array type noise reduction filter 20 comprises first and second noise reduction filters 20a and 20b within a signal chip 21. The noise reduction filters 20a and 20b within the single chip 21 are each comprised of a ground electrode 22, an inductance portion 27a or 27b, and two capacitance portions 24a and 25a, or 24b and 25b, and are each formed in the shape of a pi (π). The ground electrode 22 forms a ground portion, and the inductance portion 27a or 27b is formed of a coil-shaped conductor pattern. On the other hand, each noise reduction filter can be constructed to have one inductance portion and one capacitance portion by each employing one capacitance portion. In this construction, the gradient of the interference characteristic graph descends slowly, thus manifesting attenuation characteristics at higher frequencies.

In the array type noise reduction filter according to the preferred embodiment of this invention, the ground electrode 22 is arranged at approximately the center portion within the chip 21, and first capacitance portions 24a and 25a, or second capacitance portions 24b and 25b are respectively arranged over and under the ground electrode 22. Both the capacitance portions and the ground electrode are each preferably formed as a plate-shaped conductor layer. In the preferred embodiment of this invention, the two structures can be called a conductor layer for convenience of description.

Further, spaces for arranging the inductance portions 27a and 27b are obtained at the upper and lower portions within the chip 21 on the basis of the ground electrode 22 by the arrangement structure of the ground electrode 22 and the capacitance portions within the chip 21. The inductance portions 27a and 27b are each arranged at one portion selected of the upper and lower spaces, such that the inductance portions 27a and 27b are arranged in the noise reduction filters 20a and 20b, respectively. Here, in the case that the inductance portion 27a is selectively arranged at the lower position in the first noise reduction filter 20a so as to minimize the mutual electromagnetic interference generated between the inductance portions 27a and 27b of the first and second noise reduction filters 20a and 20b, the induction portion 27b is selectively arranged at the upper position in the second noise reduction filter 20b, such that the inductance portions 27a and 27b are arranged to be spaced apart from each other. Especially, in such a structure, electromagnetic interference can be effectively reduced by the ground electrode which is a conductor pattern.

As described above, the present invention is characterized by the arrangement structure in which the inductance portions 27a and 27b of the noise reduction filters 20a and 20b are arranged over or under different capacitance portions so as to minimize mutual electromagnetic interference. As shown in the preferred embodiment, the inductance portion 27a of the first noise reduction filter 20a is arranged under the second capacitance 25a, and the inductance portion 27b of the second noise reduction filter 20b is arranged over the first capacitance portion 24b. Thereby, the two inductance portions 27a and 27b are arranged to be spaced apart from each other, and can be electromagnetically separated by the ground electrode 22 formed of a plate-shaped conductor. Therefore, in the array type noise reduction filter such as the preferred embodiment of this invention, the mutual inductance coupling generated between two noise reduction filters can be minimized, thereby significantly reducing crosstalk.

In the preferred embodiment of this invention, the ground electrode 22 is formed as a common electrode shared between the first and second noise reduction filters 20a and 20b. However, the ground electrode 22 can be formed as individual electrodes for exclusive use of each noise reduction filter. If the ground electrode 22 is formed as the common electrode as in the preferred embodiment of this invention, the inductance portions can be effectively separated from each other by using the ground electrode 22, and the manufacturing process of the noise reduction filters can be simplified by forming only one ground electrode. On the other hand, if separated ground electrodes are formed, the position of each noise reduction filter can be adjusted up or down, such that the filter arrangement can be adjusted so as to control the distance between the inductance portions or reduce unnecessary spaces in which the inductance portions are not arranged.

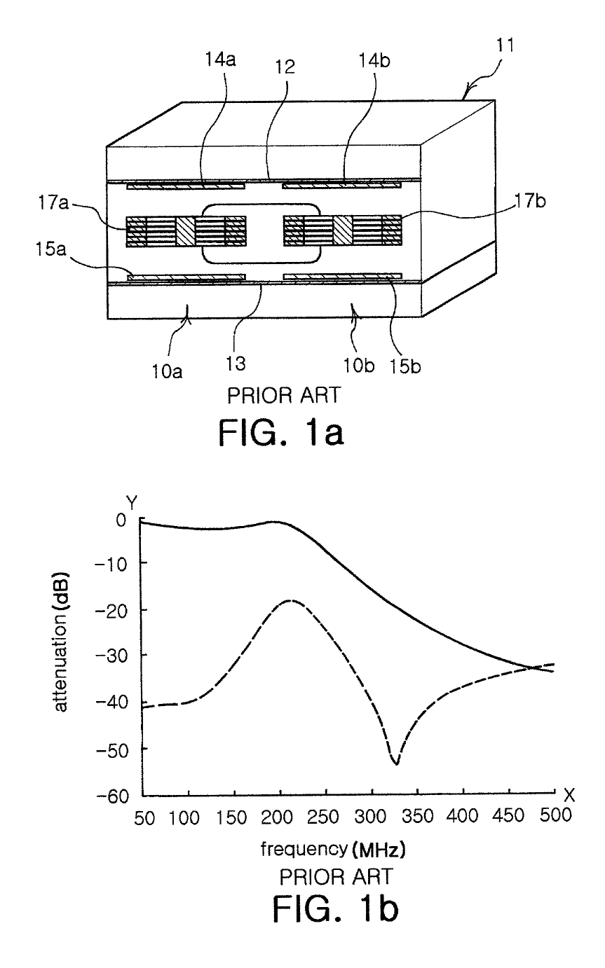

FIG. 2b is a graphic view showing the improved electromagnetic interference characteristics of the array type noise reduction filter of this invention. Referring to FIG. 2b, a part shown with a dotted line represents crosstalk due to the mutual inductance. FIG. 2b shows that crosstalk generated in the array type noise reduction filter of this invention can be remarkably decreased in comparison with the conventional array type noise reduction filter of FIG. 1b.

As described above, the reduction of the electromagnetic interference can be obtained by separating inductance portions of two noise reduction filters by the ground electrode, and arranging the inductance portions to be spaced apart from each other.

The array type noise reduction filter of this invention is not limited in the number of the noise reduction filters arranged within the chip. In other words, the array type noise reduction filter of this invention can be embodied to include more than two noise reduction filters.

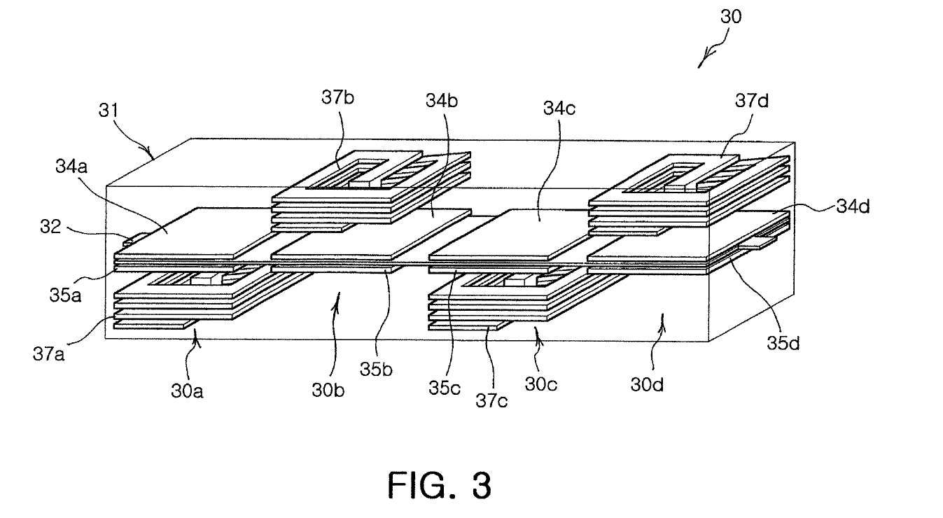

FIG. 3 is a schematic perspective view showing another array type noise reduction filter 30 having four noise reduction filters 30a, 30b, 30c and 30d according to another preferred embodiment of this invention. Similar to the array type noise reduction filter of FIG. 2a, a ground electrode 32 is horizontally arranged at approximately the center portion within a chip 31. The ground electrode 32 is formed of a single layer as a common ground electrode for the noise reduction filters 30a to 30d. Four first and second capacitance layers 34a and 35a, 34b and 35b, 34c and 35c, and 34d and 35d are each arranged over and under the ground electrode 32. The first and second capacitance layers 34a and 35a, 34b and 35b, 34c and 35c, and 34d and 35d are each arranged at opposite positions on the basis of the ground electrode 32.

In such an arrangement, separated spaces are formed in the upper and lower portions within the chip separated by the ground electrode 32. Then, the inductance portions 37a, 37b, 37c and 37b are respectively arranged at the separated spaces per the noise reduction filters 30a, 30b, 30c and 30d. At this time, the inductance portions 37a, 37b, 37c and 37d are alternately arranged under the second capacitance portions 35a and 35c and over the first capacitance portions 34b and 34d of the noise reduction filters 30a to 30d, respectively. As shown in FIG. 3, in the case of an array type noise reduction filter having more than three noise reduction filters, the inductance portions can be arranged in a zigzag pattern on the basis of the ground electrode.

Consequently, in the arrangement structure of the array type noise reduction filter of this invention, the inductance portions of adjacent noise reduction filters are spaced apart from each other, and are separated by the ground electrode, thus minimizing electromagnetic interference phenomenon.

As described above, the π-shaped noise reduction filter of FIG. 3 can be modified by omitting one of the first and second capacitance portions. In such a modified structure, the capacitance portion is connected to one of the input and output ports of each noise reduction filter so as to realize the same characteristics.

Therefore, when the noise reduction filters each employing one capacitance portion are embodied, preferably each capacitance portion is arranged at the same position, for example, over or under the ground electrode for convenience of the manufacture for forming the input or output ports.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. For example, the above preferred embodiments just show that the noise reduction filters are arranged in a line in the array type noise reduction filter. However, that is not to exclude an embodiment of the array type noise reduction filter having two-dimensional array structure.

As described above, the present invention provides an array type noise reduction filter, in which adjacent inductance portions are alternately arranged over and under the ground electrode in a plurality of noise reduction filters composing the array type noise reduction filter such that the adjacent inductance portions are arranged to be spaced apart from each other on the basis of the ground electrode arranged at the center portion of a chip, thus reducing the generation of mutual inductance. Further, the present invention is advantageous in that it can effectively prevent mutual electromagnetic interference from occurring by forming the ground electrode formed of a conductor layer as one common electrode.

What is claimed is:

1. An array type noise reduction filter, comprising:
a plurality of noise reduction filters horizontally arranged within a single chip, each comprising,
a conductor layer comprised of a ground portion arranged at approximately the center portion within the chip, and at least one capacitance portion arranged at at least one position over or under the ground portion, and
an inductance portion arranged over or under the conductor layer;
wherein an inductance portion of another noise reduction filter adjacent to a noise reduction filter having an inductance portion arranged over the conductor layer is arranged under the conductor layer.

2. The array type noise reduction filter according to claim 1, wherein the ground portion is formed as a common electrode for a plurality of noise reduction filters.

3. The array type noise reduction filter according to claim 1, wherein the inductance portion is formed of a coil-shaped conductor pattern.

4. The array type noise reduction filter according to claim 1, wherein the capacitance portion is comprised of a first capacitance portion arranged over the ground portion and a second capacitance portion arranged under the ground portion to be opposite the first capacitance portion.

5. The array type noise reduction filter according to claim 1, wherein a plurality of noise reduction filters are arranged in a line within the single chip.

6. An array type noise reduction filter having a single chip shape, comprising:
a conductor layer comprised of a ground electrode horizontally arranged at approximately the center portion within the chip, and a plurality of capacitance portions each arranged at least one position over and under the ground electrode; and
a plurality of inductance portions each arranged over or under the conductor layer at which a plurality of capacitance portions are respectively arranged,
wherein a plurality of inductance portions are alternately arranged over and under the conductor layer such that any one inductance portion and its most adjacent inductance portion are separated by the ground electrode.
